(19) United States
(12) Patent Application Publication
(10) Pub. No.: US 2009/0147583 A1
(43) Pub. Date: Jun. 11, 2009

(54) SEMICONDUCTOR MEMORY DEVICE HAVING MAT STRUCTURE

(75) Inventor: Chan-Ho KIM, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/265,486

(22) Filed: Nov. 5, 2008

(30) Foreign Application Priority Data
Dec. 11, 2007 (KR) 10-2007-0128328

(51) Int. Cl. G11C 16/04; H01L 29/788

(52) U.S. Cl. 365/185.12; 257/315; 365/185.05; 257/E29.3

(57) ABSTRACT

A semiconductor memory device having a mat structure. The semiconductor memory device may comprise a first mat having a plurality of first memory cells and a second mat having a plurality of second memory cells. The first and second mats are formed in a single well region. The first and second mats may share a first well of a first conductivity type, and the first well may be formed in a second well of a second conductivity type. The second well may be formed in a semiconductor substrate of the first conductivity type. As a result, the semiconductor memory device according to embodiments of the present invention provide for higher integration density.

### CROSS-REFERENCE TO RELATED APPLICATIONS

This U.S. non-provisional patent application claims priority under 35 U.S.C. § 119 of Korean Patent Application No. 10-2007-0128328 filed on Dec. 11, 2007, the entire contents of which are incorporated herein by reference.

### BACKGROUND

Embodiments of the present invention disclosed herein relate to semiconductor memory devices and more particularly, to a semiconductor memory device having a mat structure.

Semiconductor memory devices are generally used to store data. Semiconductor memory devices may be classified into volatile and nonvolatile types. Nonvolatile memories are capable of maintaining their own data even without a supply of power. Nonvolatile memories usually include, for example, flash memories, programmable random access memories (PRAMs), ferroelectric RAMs (FRAMs), magnetic RAMs (MRAMs), and charge trap flash (CTF) memories. In particular, flash memories are becoming popular as portable reservoirs of data on the merits of high integration density.

With higher integration density of semiconductor memory devices, new challenges arise. For example, twin well structures are known to cause inefficiencies. To surmount the inefficiencies arising from the twin well structures, triple well structures have been proposed. Typically, a triple well structure is formed by including a P-well (substrate), an N-well, and a pocket P-well (PP-well). In the triple well structure, bias voltages may be applied differently to such wells. This enables an erasing operation in a high-density semiconductor memory device such as a flash memory device.

FIG. 1 is a vertical section illustrating a bias condition for an erasing operation of a flash memory device. Referring to FIG. 1, a voltage of 0V is applied to a substrate (P-sub) while a high voltage of 20V is applied to an N-well and a pocket P-well (PP-well). A drain (D) and a source (S) are floated. A voltage of 0V is applied to a control gate. Under this bias condition, electrons move toward the substrate from a floating gate (FG). Then, a threshold voltage of a memory cell becomes lower (an erased state).

As shown in FIG. 1, in such a triple well structure, the substrate and the pocket P-well (PP-well) are separated from each other by the N-well. Thus, the substrate and the pocket P-well may be charged by different bias voltages.

Storage capacities of semiconductor memory devices have been steadily increased over a long period of time. The storage capacity is proportional to the degree of integration of the semiconductor memory device. The degree of integration of the semiconductor memory device has been doubled every year according to what is called Hwang's law. Through such an evolutionary trend, it is nowadays achievable to produce a semiconductor memory device having significantly larger storage capacity. In the meantime, an increasing activation rate of data exchange in communication networks requires large amounts of data to be processed at a time. For these reasons, semiconductor memory devices are in need of enhancing their integration density in order to store even more data.

One way for extending a storage capacity is to increase the number of memory cells included in a semiconductor memory device. As the number of memory cells increases, the memory cell array becomes wider in area. However, a wider memory cell array causes connection lines (e.g., word and bit lines) to be longer over the memory cell array. Longer connection lines result in an increase of parasitic capacitance. As a result, it takes a long time to charge or discharge the connection lines, which increases a data reading or programming time.

To solve those problems, there has been a methodological way for dividing a memory cell array into a plurality of sections. Peripheral circuits are arranged between divided mats of the memory cell array in the semiconductor memory device. Such peripheral circuits, including row selectors, page buffers, and so forth, operate independently of each other and are coupled each to their corresponding mats.

FIG. 2 is a block diagram illustrating a semiconductor memory device 100 with two mats 110 and 120. Referring to FIG. 2, the semiconductor memory device 100 includes the mats 110 and 120 which are arranged along a row, and peripheral circuits 130 and 140 corresponding to the mats 110 and 120, respectively. The peripheral circuits 130 and 140 function to selectively access the mats 110 and 120, respectively. The semiconductor memory device 100 shown in FIG. 2 includes two mats, but two or more mats may be included therein.

Hereinafter, when referring to a structure of the mat 110, such reference will be representative of mats 110 and 120, because the two mats 110 and 120 include substantially the same architecture. The mat 110 includes a plurality of memory cells. Memory cells may be arranged in a NAND or NOR structure. Referring to FIG. 2, the mat 110 is organized of NAND strings 111˜11n. The NAND strings 111˜11n may have the same structure as each other. Thus, a structure of the NAND string 111 will be explained as an example.

The NAND string 111 may be formed of a bit line BL, a bit-line contact BLC, a string selection line SSL, word lines WL, floating gates FG, and a ground selection line GSL. The peripheral circuit 130 stores data into memory cells of the mat 110, or reads data from the memory cells of the mat 110.

As shown in FIG. 2, a spatial gap G is provided between the mats 110 and 120. In designing the semiconductor memory device 100, the mats 110 and 120 are made in the same structure. In fabricating the semiconductor memory device 100, the mats 110 and 120 are arranged in a row or column direction. In other words, the spatial gap G acts as an interval that distinguishes the mats 110 and 120 from each other. This is because there is a need to isolate well regions in which the mats 110 and 120 are formed independently. Here, it can be seen that the integration density of the semiconductor memory device could be lower since the spatial gap G cannot contribute to the storing of data. Well structures of the mats 110 and 120 will be described in conjunction with FIG. 3.

FIG. 3 is a vertical section of FIG. 2, taken along line A-A′. Referring to FIG. 3, the mats 110 and 120 are formed independently in N-wells and pocket P-wells, the N-well and pocket P-well pairs being isolated from each other for the mats. In other words, the mat 110 is formed in one pocket P-well of a pocket P-well pair and the mat 120 is formed independently in another pocket P-well of the pocket P-well pair. Similarly, the mat 110 is formed in one N-well of an N-well pair and the mat 120 is formed independently in another N-well of the N-well pair. The mats 110 and 120 are fabricated as follows.

First, the two N-well regions are formed in a substrate (P-sub). The N-well regions are isolated from each other. Then, the pocket P-well regions (PP-well) are formed in the N-well regions, respectively. Device isolation layers 210 are formed in the pocket P-well regions. Floating gates 220 are each formed in dielectric layers 230. Word lines 240 are formed on the dielectric layers 230. While the reference numerals are directed toward elements of mat 110, it should be understood that the description of the elements also applies to the mat 120.

The mats 110 and 120 are each formed in the isolated pocket P-well regions. The spatial gap G is generated between the mats 110 and 120 so as to separate the pocket P-well regions. As aforementioned, the semiconductor memory device could be degraded in integration density because the spatial gap G is not helpful for storing data therein. In this structure shown in FIG. 2, the integration density of the semiconductor would be lowered correlating to the number of mats.

FIG. 4 is a block diagram illustrating a semiconductor memory device 300 having four mats 310, 320, 330, and 340. Referring to FIG. 4, the semiconductor memory device 300 may include the mats 310˜340 arranged in a matrix of rows and columns, and peripheral circuits 350, 360, 370, and 380 corresponding to the mats 310˜340, respectively.

Hereinafter, only a structure of the mat 310 will be described as the mats 310˜340 have substantially the same structure as each other. The mat 310 includes a plurality of memory cells. Memory cells may be arranged in a NAND or NOR structure. The mat 310 includes NAND strings 311˜31n. The NAND strings 311˜31n may have the same structure as the NAND strings 111˜11n shown in FIG. 2, so a description of the NAND strings 311˜31n will be omitted for the sake of brevity.

Referring to FIG. 4, the mats 310˜340 are arranged along row and column directions. Spatial gaps are provided to separate well regions because the mats 310˜340 are respectively formed in the well regions different from each other. As a result, the semiconductor memory device 300 could be disadvantageous in integration density because the spatial gaps G are present along the column direction B-B′ as well as in the row direction C-C′. The well structures of the mats 310 to 340 will be described with reference to FIG. 5.

FIG. 5 is a vertical section of FIG. 4, taken along line B-B′. The cross-sectional view of FIG. 4 taken along line C-C′ is similar to the cross-sectional view of FIG. 2 that is taken along line A-A′, so the for the sake of brevity, the cross-sectional view of FIG. 4 taken along line C-C′ is not shown here. As shown in FIG. 5, the mats 310 and 330 are each formed in N-wells and pocket P-wells different from each other. The mats 310 and 330 are fabricated as follows.

Two N-wells are first formed on a substrate P-sub. The N-wells are separated. Then, the pocket P-wells (PP-well) are each formed in the N-wells. N+ impurity regions, which may function as drains or sources, are each formed in the pocket P-wells. Floating and control gates, FG and CG, are formed over the N+ impurity regions. A transistor closest to a bit line BL operates as a string selection transistor SST. A transistor farthest from the bit line BL operates as a ground selection transistor GST. A source of the ground selection transistor GST is connected to a common source line CSL. The transistors, which are interposed between the string and ground selection transistors SST and GST, operate as memory cells of the semiconductor memory device 300.

As illustrated in FIG. 5, the mats 310 and 330 are formed in the pocket P-wells (PP-well) isolated from each other. The spatial gap G is present between the mats 310 and 330, separating the pocket P-well from each other. As previously mentioned, these spatial gaps G decrease the integration efficiency of the semiconductor memory because they cannot be used for storing data therein.

### SUMMARY

Embodiments of the present invention are directed to solve the aforementioned problems, providing a semiconductor memory device with a smaller layout area by forming mats in a single well region.

An aspect of the present invention is a semiconductor memory device comprised of: a first mat having a plurality of first memory cells; and a second mat having a plurality of second memory cells. The first and second mats are formed in a single well region.

In an embodiment, the first and second mats share a first well disposed in the single well region. The first well may comprise a first conductivity type. The first well may be formed in a second well disposed in the single well region. The second well may comprise a second conductivity type and the second well may be formed in a semiconductor substrate of the first conductivity type. The first and second wells and the semiconductor substrate may be biased independently of each other. The first and second conductivity types may be opposite to each other.

In another embodiment, the first and second mats are controlled independently by peripheral circuits. The peripheral circuits may be row selectors. Each of the row selectors may be disposed at the middle of one of the first and second mats. Alternatively, each of the row selectors may be disposed at one side of the first and second mats, respectively.

In another embodiment, the first and second mats are arranged in one of row and column directions. The first and second mats may be the same in structure. The memory cells may be flash memory cells. The flash memory cells may be configured in one of NAND and NOR structures.

Another aspect of the present invention is a memory card including: a semiconductor memory device; and a controller configured to control the semiconductor memory device. The semiconductor memory device is configured by including: a first mat having a plurality of first memory cells; and a second mat having a plurality of second memory cells. The first and second mats are formed in a single well region.

The semiconductor memory device according to some embodiments of the present invention is comprised of a plurality of mats sharing a well region. According to some embodiments of the present invention, the semiconductor memory device is advanced in integration density. Moreover, the semiconductor memory device according to some embodiments of the present invention may be operable using lower power consumption and higher frequency.

A further understanding of the nature and advantages of the embodiments of the present invention herein may be realized by reference to the remaining portions of the specification and the attached drawings.

### BRIEF DESCRIPTION OF THE DRAWINGS

Non-limiting and non-exhaustive embodiments of the present invention will be described with reference to the following figures, wherein like reference numerals refer to like parts throughout the various figures unless otherwise specified. In the figures:

FIG. 1 is a vertical section illustrating a bias condition for an erasing operation of a flash memory device;

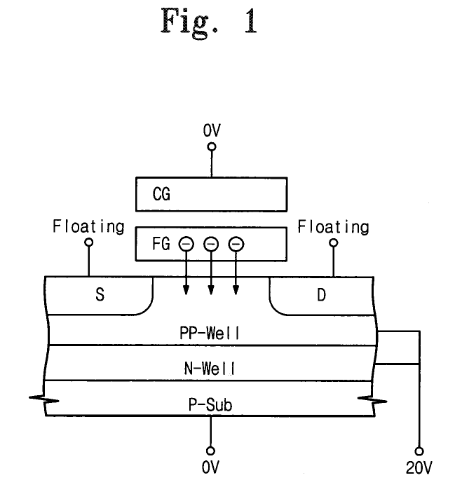

FIG. 2 is a block diagram illustrating a semiconductor memory device with two mats;

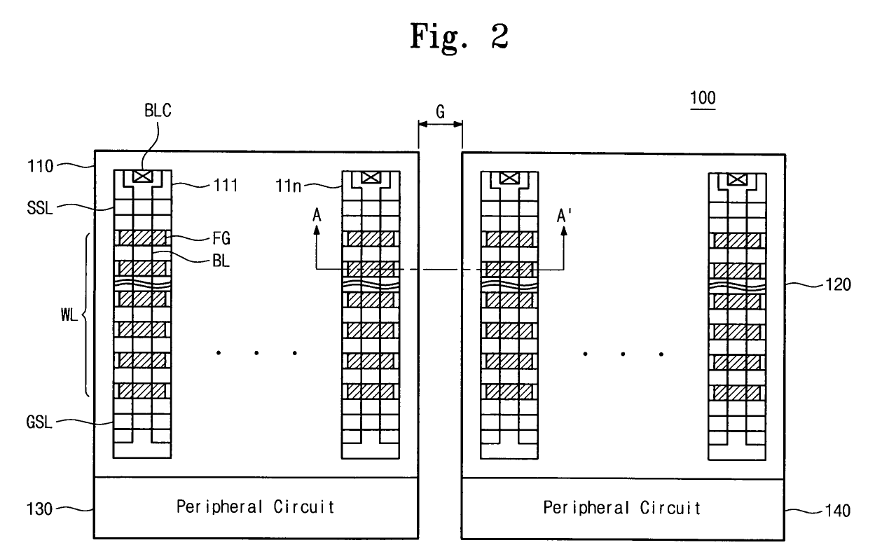

FIG. 3 is a vertical section of FIG. 2, taken along line A-A′;

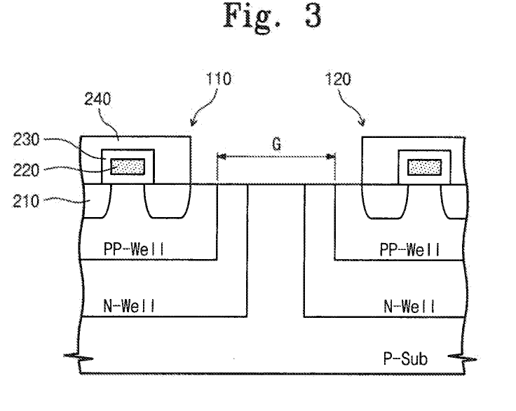

FIG. 4 is a block diagram illustrating a semiconductor memory device having four mats;

FIG. 5 is a vertical section of FIG. 4, taken along line B-B′;

FIG. 6 is a block diagram illustrating a semiconductor memory device according to a first embodiment of the present invention;

FIG. 7 is a vertical section of FIG. 6, taken along line D-D′;

FIG. 8 is a block diagram illustrating a semiconductor memory device according to a second embodiment of the present invention;

FIGS. 9(a) through 9(c) are block diagrams illustrating bias conditions of erasing, programming, and reading operations for a semiconductor memory device according to some embodiments of the present invention;

FIG. 10 is a block diagram illustrating a semiconductor memory device according to a third embodiment of the present invention;

FIG. 11 is a vertical section of FIG. 10, taken along line E-E′;

FIG. 12 is a block diagram illustrating a semiconductor memory device according to a fourth embodiment of the present invention; and

FIG. 13 is a block diagram illustrating a computing system including a semiconductor memory device in accordance with some embodiments of the present invention.

### DETAILED DESCRIPTION OF THE EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout the accompanying figures.

In these exemplified embodiments according to the present invention, a semiconductor memory device may include a PRAM, an MRAM, an FRAM, or a CTF memory, besides a flash memory device.

In these embodiments according to the present invention, mats are formed in a single well region. In other words, while the single well region may comprise more than one well, the wells in the single well region are formed in one another, or in other words, over one another, which improves a semiconductor memory device in degree of integration density. Hence, there is absent a region that separates laterally adjacent well regions from each other.

Hereinafter, various example embodiments of the present invention in conjunction with the accompanying drawings will be described.

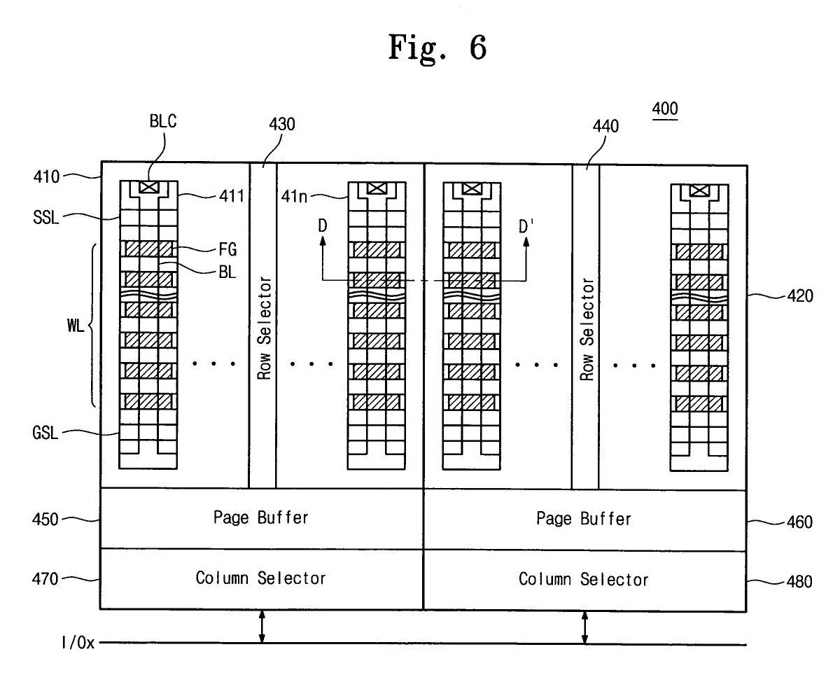

FIG. 6 is a block diagram illustrating a semiconductor memory device 400 according to a first embodiment of the present invention. Referring to FIG. 6, the semiconductor memory device 400 may be comprised of two mats 410 and 420, row selectors 430 and 440, page buffers 450 and 460, and column selectors 470 and 480.

As the mats 410 and 420 have substantially the same structure as each other, hereinafter, a structure of the mat 410 will be described as a representative structure. The mat 410 includes a plurality of memory cells. The memory cells may be arranged in a NAND or NOR structure. The mat 410 includes NAND strings 411˜41n. Each of the NAND strings 411˜41n are formed having substantially the same structure, so a structure of the NAND string 411 will be described as an example.

The NAND string 411 may be formed of a bit line BL, a bit-line contact BLC, a string selection line SSL, word lines WL, floating gates FG, and a ground selection line GSL.

The row selector 430 may be located at the middle of the mat 410 to decrease length of the word lines WL connected thereto. The row selector 430 may drive the word lines WL in response to row addresses (not shown). For example, in a reading operation, the row selector 430 may apply a read voltage to a selected word line, while applying a pass voltage to deselected word lines.

The page buffer circuit 450 may be coupled to the bit lines BL of the NAND strings 411˜41n. Page buffers of the page buffer circuit 450 may operate as sense amplifiers or writing drivers. In the reading operation, the page buffer circuit 450 senses voltages of the bit lines BL to detect data. In a writing operation, the page buffer circuit 450 applies voltages to the bit lines BL to store data.

The column selector 470 selects the bit lines BL in response to column addresses (not shown). Data corresponding to a selected bit line BL may be output externally through an input/output line (I/Ox). The mats 410 and 420 are formed in a single well region. Thus, there is no need of comprising a region that separates well regions from each other, which improves the integration density of the semiconductor memory device 400.

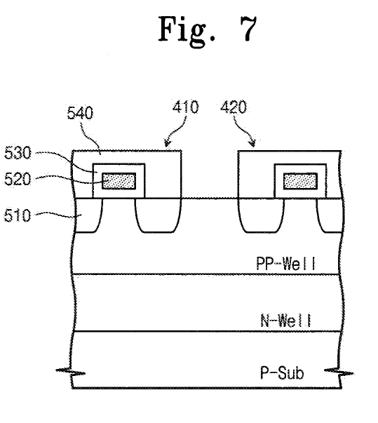

Well structures of the mats 410 and 420 will now be described with reference to FIG. 7. The row selectors 430 and 440 do not share a pocket P-well (PP-well) with the mats 410 and 420 because the row selectors 430 and 440 operate independent of the mats 410 and 420. The row selectors 430 and 440 are formed in an additional well region that is placed in the pocket P-well.

FIG. 7 is a vertical section of FIG. 6, taken along line D-D′. Referring to FIG. 7, the mats 410 and 420 are formed in the same N-well and pocket P-well PP-well. The process of forming mats 410 and 420 will hereinafter be described.

First, the N-well may be formed in a substrate (P-sub). Then, the pocket P-well region may be formed in the N-well. At least one device isolation layer 510 may then be formed in the pocket P-well. A floating gate 520 may be formed in a dielectric layer 530. A word line 540 may be formed on or around the dielectric layer 530.

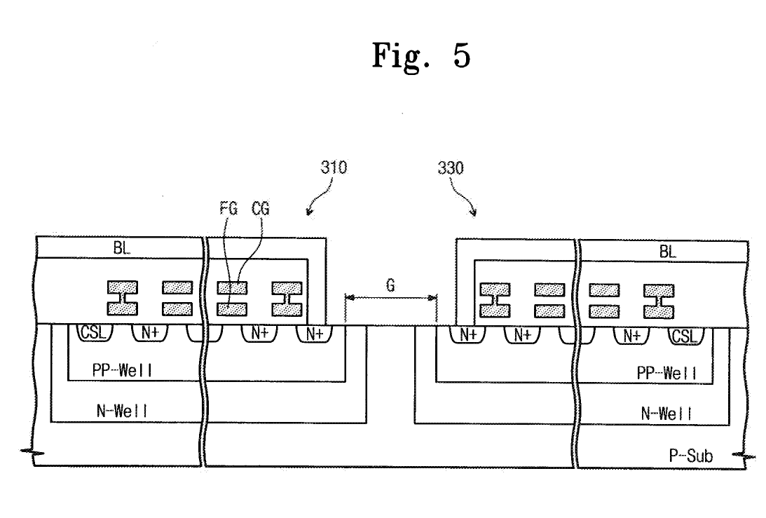

The mats 410 and 420 may be formed in the pocket P-well. Therefore, the spatial gap G (of FIG. 5), which separates the pocket P-wells (refer to FIG. 5) is not generated between the mats 410 and 420. Thus, the semiconductor memory device 400 may include more memory cells therein. Accordingly, a degree of integration of the semiconductor memory device 400 may be enhanced.

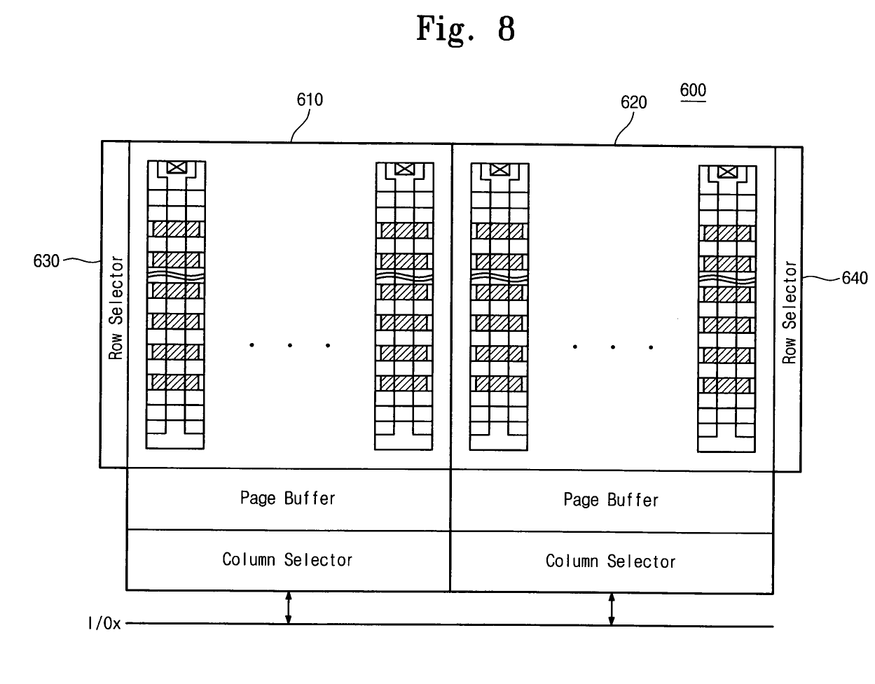

FIG. 8 is a block diagram illustrating a semiconductor memory device 600 according to a second embodiment of the present invention. Referring to FIG. 8, each of the row selectors 630 and 640 may be disposed at one side of the mats 610 and 620, respectively. As in FIG. 6, a degree of integration of the semiconductor memory device 600 can be higher because the mats 610 and 620 are formed in the single pocket P-well (PP-well).

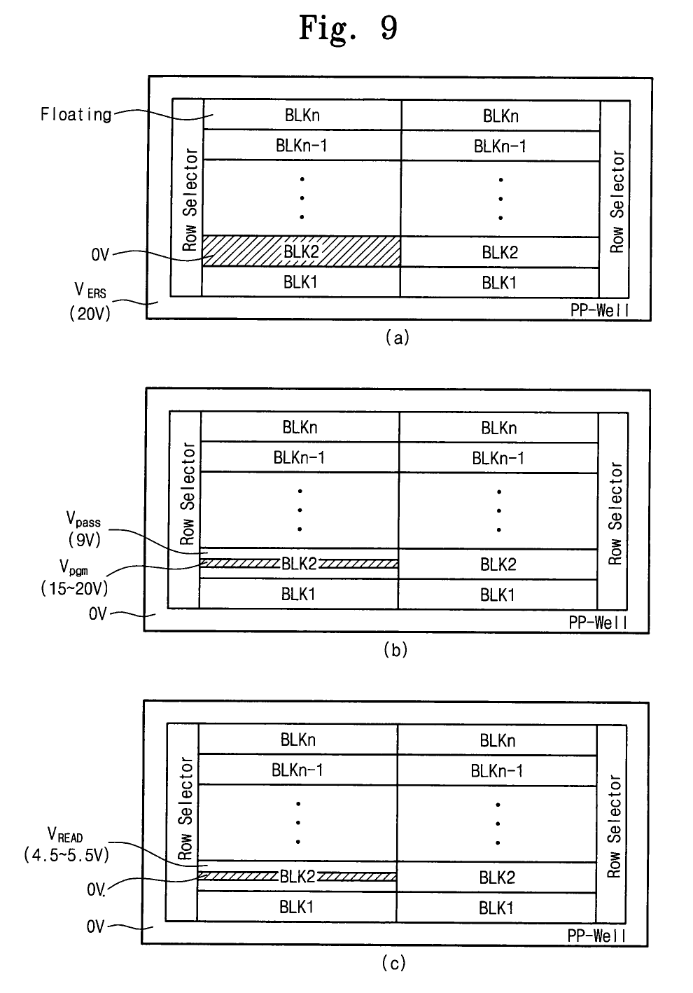

Hereinafter, erasing, programming, and reading operations of the semiconductor memory device (e.g., a flash memory device) according to some embodiments of the present invention in conjunction with FIGS. 9(a) through 9(c) will be described.

FIG. 9(a) is a block diagram illustrating a bias condition for the erasing operation of the semiconductor memory device according to some embodiments of the present invention. In a flash memory device, the erasing operation may be carried out in the unit of a block. Each mat includes a plurality of blocks BLK1˜BLKn. During the erasing operation, an erase voltage V_{ERS} of about 20V may be applied to the pocket P-well. To selectively erase blocks, a voltage of 0V may be applied to word lines of a selected block BLK2 (indicated by hatchings) while word lines of deselected blocks BLK1 and BLK3˜BLKn may be floated.

FIG. 9(b) is a block diagram illustrating a bias condition for the programming operation of the semiconductor memory device according to some embodiments of the present invention. In the flash memory device, the programming operation may be carried out in the unit of a page. Each block includes a plurality of pages. During the programming operation, a voltage of 0V may be applied to the pocket P-well. To selectively program pages, a program voltage Vpgm of about 15V˜20V, may be applied to word lines of a selected page (indicated by hatchings) while a pass voltage Vpass of about 9V may be applied to word lines of deselected pages, e.g., of BLK2.

FIG. 9(c) is a block diagram illustrating a bias condition for the reading operation of the semiconductor memory device according to some embodiments of the present invention. In the flash memory device, the reading operation may be carried out in the unit of a page. In the reading operation, a voltage of 0V may be applied to the pocket-P well. To selectively read pages, a voltage of 0V may be applied to word lines of a selected page (indicated by hatchings) and a read voltage V_{READ} of about 4.5V˜5.5V may be applied to word lines of deselected pages. As the bias conditions mentioned above are applicable to single level cells, multi-level cells may be associated with other bias conditions different from the aforementioned.

With the aforementioned procedures, the erasing, programming, and reading operations are conducted in the semiconductor memory device according to some embodiments of the present invention. Therefore, such bias conditions are available for the erasing, programming, and reading operations of the semiconductor memory device.

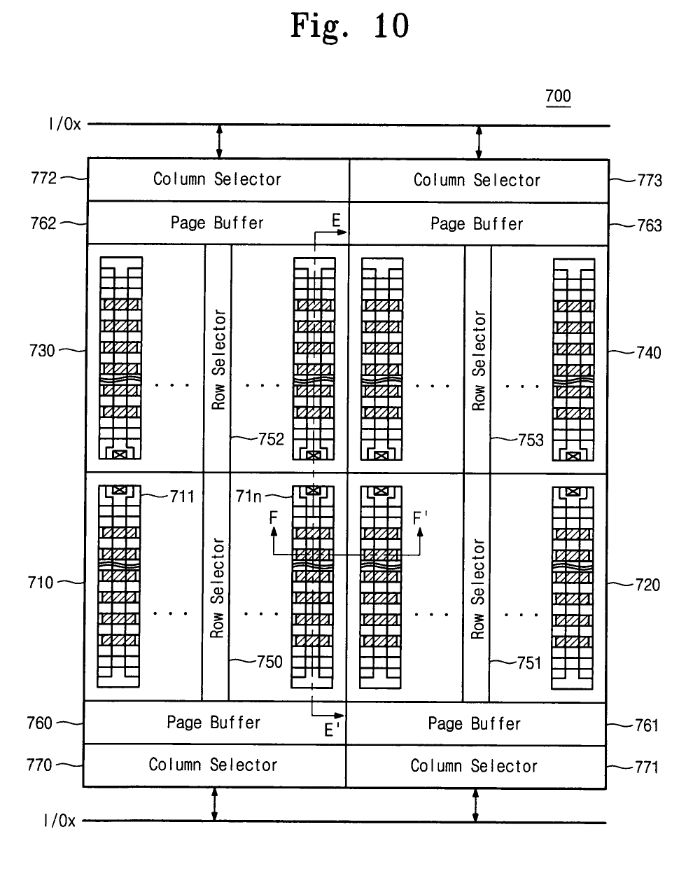

FIG. 10 is a block diagram illustrating a semiconductor memory device according to a third embodiment of the present invention. Referring to FIG. 10, the semiconductor memory device 700 may include four mats 710, 720, 730, and 740 (710˜740) which are arranged in a matrix formed of rows and columns. The memory device 700 may include row selectors 750, 751, 752, and 753 (750˜753), page buffer circuits 760, 761, 762, and 763 (760˜763), and column selectors 770, 771, 772, and 773 (770˜773). As the four mats 710˜740 may have substantially the same architecture as each other, a structure of the mat 710 will be described below as a representative structure.

The mat 710 includes a plurality of memory cells. The memory cells may be arranged in a NAND or NOR structure. For example, FIG. 10 shows NAND strings 711˜71n, each of which may be formed of the memory cells. Each NAND string (e.g., 711) may have substantially the same structure as the NAND string 411 shown in FIG. 6. Therefore, the structure of the NAND string 711 will not be further described herein for the sake of brevity.

The row selector 750 may be disposed at the middle of the mat 710. The row selector 750 drives the word lines WL in response to row addresses (not shown). For example, during a reading operation, the row selector 750 may apply a voltage of 0V to a selected word line, while applying the read voltage to deselected word lines (e.g., in a case of single level cell).

The page buffer circuit 760 may be coupled to bit lines of the NAND strings 711˜71n. Page buffers of the page buffer circuit 760 may operate as sense amplifiers or writing drivers. In the reading operation, the page buffer circuit 760 senses voltages of the bit lines to detect data. In the writing operation, the page buffer circuit 760 applies voltages to the bit lines BL to store data.

The column selector 770 may operate to select the bit lines in response to column addresses (not shown). Data corresponding to a selected bit line may be externally output through the input/output line (I/Ox). The mats 710˜740 of the semiconductor memory device 700 shown in FIG. 10 are formed in a single well region. Thus, a region separating well regions is unnecessary, and as a result, a degree of integration of the semiconductor memory device is increased.

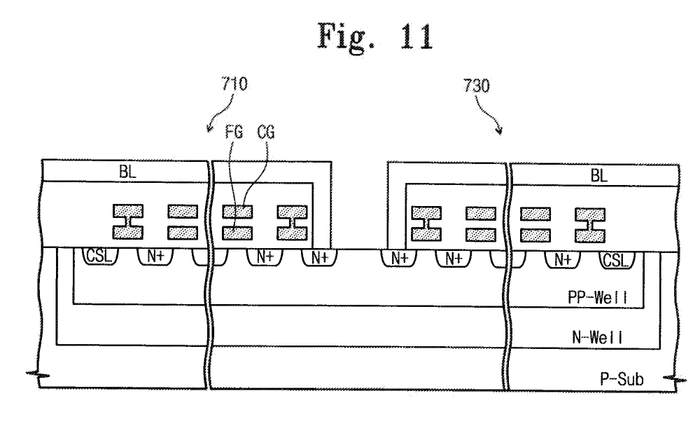

FIG. 11 is a vertical section of FIG. 10, taken along line E-E′. Since the section indicated by F-F′ of FIG. 11 is substantially the same as the section indicated by D-D′ of FIG. 6, the structure along F-F′ of FIG. 11 will not be further described for the sake of brevity. Referring to FIG. 11, the mats 710 and 730 may be formed on the same N-well and pocket P-well (PP-well).

Hereinafter, a process of fabricating the mats 710 and 730 will be described. First, a single N-well region is formed in a substrate (P-sub). Then, a single pocket P-well is formed in the N-well region. N+ type impurity regions, which may function as drains or sources, are formed in the pocket P-well. Floating and control gates FG and CG may be formed over the N+ impurity regions. A transistor closest to the bit line BL may operate as the string selection transistor SST. A transistor farthest from the bit line BL may operate as the ground selection transistor GST. A source of the ground selection transistor GST may be connected to a common source line CSL. The transistors connected in series between the string and ground selection transistors SST and GST operate as memory cells.

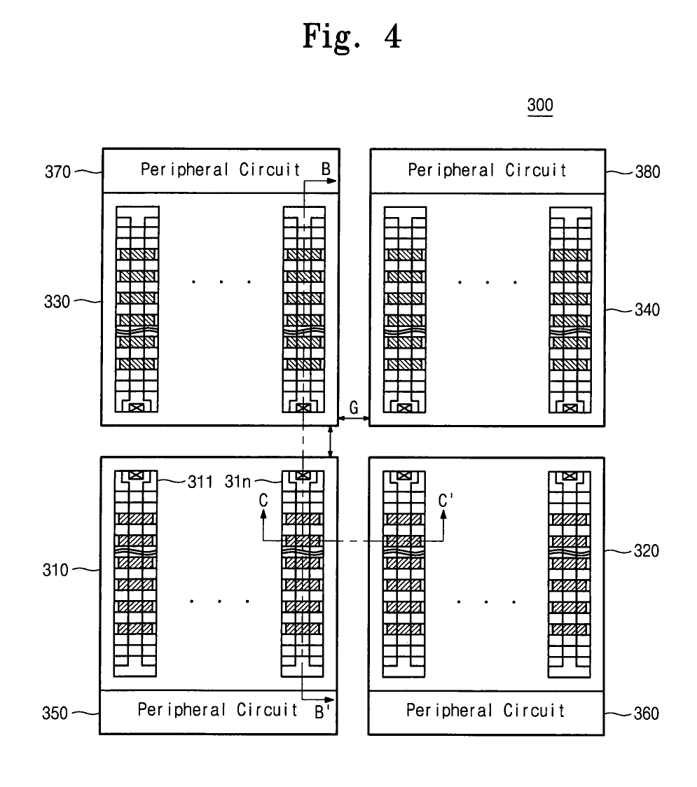

As shown in FIG. 11, the mats 710 and 730 are formed in the single pocket P-well (PP-well). The spatial gaps G for separating the pocket P-well regions (as shown in FIG. 4 or 5) are not present between the mats 710 and 730. Therefore, the semiconductor memory device 700 is able to accommodate more memory cells. Accordingly, the integration density of the semiconductor memory device 700 is improved.

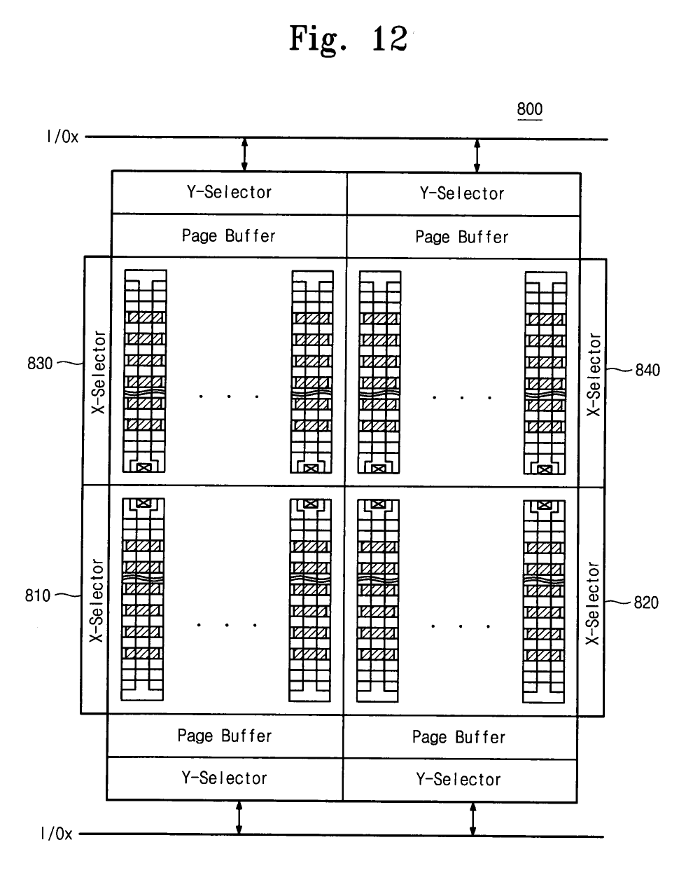

FIG. 12 is a block diagram illustrating a semiconductor memory device according to a fourth embodiment of the present invention. Referring to FIG. 12, each row selector (X-Selector) may be located at one side of mats 810, 820, 830 and 840 (810˜840), respectively. And each of a plurality of page buffers (Page Buffers) may be located orthogonally to one of the row selectors and located at another side of mats 810, 820, 830 and 840 (810˜840) different from the sides having located thereat the row selectors. Each of a plurality of column selectors (Y-Selector) may be coupled to one of the page buffers (Page Buffers). As in the case illustrated in FIG. 10, the semiconductor memory device 800 increases integration density because the mats 810, 820, 830 and 840 are formed in the single pocket P-well (PP-well). Although the semiconductor memory devices according to the aforementioned embodiments are described as having two or four mats, the described embodiments of the present invention may not be restrictive to only two or four mats, and may have two or more number of mats.

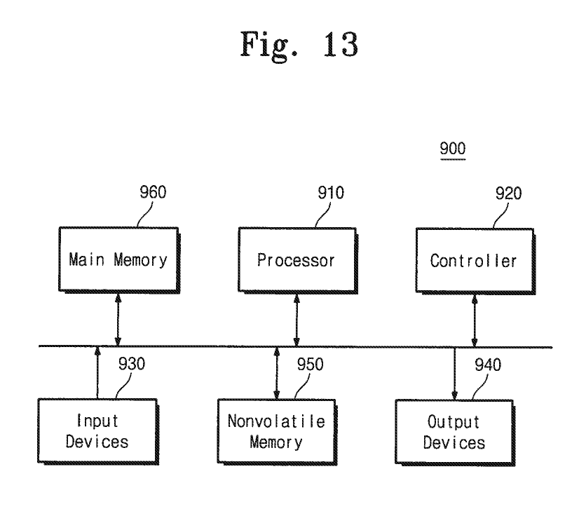

FIG. 13 is a block diagram illustrating a computing system 900 including a semiconductor memory device in accordance with some embodiments of the present invention. Referring to FIG. 13, the computing system 900 may be comprised of a processor 910, a controller 920, input devices 930, output devices 940, a nonvolatile memory 950, and a main memory 960. In FIG. 13, a solid line represents a system bus through which data or commands are transferred.

The computing system 900 according to some embodiments of the present invention may receive data through the input devices 930 (e.g., keyboards or cameras). The received data may be stored in the main memory 960. Data processed by the processor 910 may be stored in the nonvolatile memory 950 or the main memory 960. The output devices 940 may output data from the nonvolatile memory 950 or the main memory 960. For example, the output devices 940 may include display units or speakers, among other possibilities.

The nonvolatile memory 950 may be configured in a mat structure according to some embodiments of the present invention. A size of the computing system 900 may be scaled down because the nonvolatile memory 950 is denser.

The nonvolatile memory 950 and/or the controller 920 can be mounted on the system 900 by way of various types of packages. For instance, the flash memory 950 and/or the controller 920 may be placed thereon by any package type, e.g., Package-on-Package (PoP), Ball Grid Arrays (BGAs), Chip Scale Packages (CSPs), Plastic Leaded Chip Carrier (PLCC), Plastic Dual In-line Package (PDIP), Die in Waffle Pack, Die in Wafer Form, Chip-On-Board (COB), CERamic Dual In-line Package (CERDIP), Plastic Metric Quad Flat Pack (MQFP), Thin Quad Flat Pack (TQFP), Small Outline (SOIC), Shrink Small Outline Package (SSOP), Thin Small Outline (TSOP), Thin Quad Flat Pack (TQFP), System In Package (SIP), Multi-Chip Package (MCP), Wafer-level Fabricated Package (WFP), Wafer-level Processed Stack Package (WSP), or Wafer-level Processed Package (WSP). The nonvolatile memory 950 and the controller 920 may construct a memory card.

Although not shown in FIG. 13, it should be understood by those skilled in the art that a power supply unit may be provided to the computing system 900. And, if the computing system 900 is a kind of mobile device, it may be further comprised of a battery for supplying power thereto.

The computing system according to some embodiments of the present invention is also applicable as a solid state disk (SSD). In recent years, SSD products are being spotlighted as competitive solutions capable of substituting hard disk drives (HDDs). SSDs are more advantageous than HDDs because of the inherent limitations of a HDD such as mechanically operated parts, poor operation rate, external impact concerns, and high power consumption.

The computing system according to some embodiments of the present invention may also be employed as a portable storage device. For example, the semiconductor memory system may be used as a storage device of an MP3 player, a digital camera, a PDA, or an electronic book, among other possibilities. Moreover, the computing system according to some embodiments of the present invention may be used as a storage unit for a digital television or a personal computer.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A semiconductor memory device comprising:
a first mat having a plurality of first memory cells; and
a second mat having a plurality of second memory cells,
wherein the first and second mats are formed in a single well region.

2. The semiconductor memory device of claim 1, wherein:
the first and second mats share a first well disposed in the single well region,
the first well comprises a first conductivity type,
the first well is formed in a second well disposed in the single well region,
the second well comprises a second conductivity type, and
the second well is formed in a semiconductor substrate of the first conductivity type.

3. The semiconductor memory device of claim 2, wherein the first and second wells and the semiconductor substrate are biased independently of each other.

4. The semiconductor memory device of claim 2, wherein the first and second conductivity types are opposite to each other.

5. The semiconductor memory device of claim 2, wherein the first well comprises a pocket P-well (PP-well) having at least one impurity region formed therein.

6. The semiconductor memory device of claim 5, wherein:
the first mat comprises first memory cells having first floating and control gates formed over the at least one impurity region formed in the PP-well,
the second mat comprises second memory cells having second floating and control gates formed over the at least one impurity region formed in the PP-well, and
the first memory cells are controlled independently of the second memory cells.

7. The semiconductor memory device of claim 1, wherein the first and second mats are controlled independently by peripheral circuits.

8. The semiconductor memory device of claim 7, wherein the peripheral circuits are row selectors.

9. The semiconductor memory device of claim 8, wherein each of the row selectors is disposed at the middle of one of the first and second mats.

10. The semiconductor memory device of claim 8, wherein each of the row selectors is disposed at one side of the first and second mats, respectively.

11. The semiconductor memory device of claim 1, wherein the first and second mats are arranged in one of row and column directions.

12. The semiconductor memory device of claim 1, wherein the first and second mats are substantially the same in structure.

13. The semiconductor memory device of claim 1, wherein the memory cells are flash memory cells.

14. The semiconductor memory device of claim 13, wherein the flash memory cells are configured in one of NAND and NOR structures.

15. A semiconductor memory device comprising:
at least four mats structured and arranged in columns and rows;
a plurality of row selectors, each row selector corresponding to one of the at least four mats and disposed at one side of the at least four mats, respectively;
a plurality of page buffers disposed orthogonally to one of the row selectors and disposed at another side of the at least four mats different from the sides having disposed thereat the row selectors;
a plurality of column selectors, each column selector coupled to one of the page buffers,
wherein each row selector corresponds to one of the at least four mats, each page buffer corresponds to one of the at least four mats, each column selector corresponds to one of the at least four mats, and wherein the at least four mats are formed in a single well region.

16. The semiconductor memory device of claim 15, wherein:
the at least four mats share a first well disposed in the single well region,
the first well comprises a first conductivity type,
the first well is formed in a second well disposed in the single well region,
the second well comprises a second conductivity type, and
the second well is formed in a semiconductor substrate of the first conductivity type.

17. The semiconductor memory device of claim 16, wherein:
the first well comprises a pocket P-well (PP-well) having at least one impurity region formed therein,
each of the at least four mats comprise memory cells having first floating and control gates formed over the at least one impurity region formed in the PP-well, and
the memory cells of one of the at least four mats are controlled independently of memory cells of another of the at least four mats.

18. The semiconductor memory device of claim 15, wherein the row selectors and the column selectors are independently controlled, and wherein the at least four mats are independently controlled by the independently controlled row selectors and the column selectors.

19. A memory card comprising:
a semiconductor memory device; and
a controller configured to control the semiconductor memory device,
wherein the semiconductor memory device comprises:
a first mat having a plurality of first memory cells; and
a second mat having a plurality of second memory cells,
wherein the first and second mats are formed in a single well region.

20. The memory card of claim 19, wherein:
the first and second mats share a first well disposed in the single well region,
the first well comprises a first conductivity type,
the first well is formed in a second well disposed in the single well region,
the second well comprises a second conductivity type, and
the second well is formed in a semiconductor substrate of the first conductivity type.
